(19) United States
(12) Patent Application Publication
(10) Pub. No.: US 2024/0153836 A1
(43) Pub. Date: May 9, 2024

(54) SEMICONDUCTOR DEVICE

(71) Applicant: ROHM CO., LTD., Kyoto-shi (JP)

(72) Inventor: Naoaki TSURUMI, Kyoto-shi (JP)

(21) Appl. No.: 18/414,969

(22) Filed: Jan. 17, 2024

Related U.S. Application Data
(63) Continuation of application No. PCT/JP2022/035719, filed on Sep. 26, 2022.

(30) Foreign Application Priority Data
Oct. 13, 2021 (JP) 2021-168410

(51) Int. Cl. H01L 23/31; H01L 23/00; H01L 23/495

(52) U.S. Cl. CPC H01L 23/3135; H01L 23/49513; H01L 23/49541; H01L 24/29; H01L 24/32; H01L 24/48; H01L 24/73; H01L 24/83; H01L 2224/29111; H01L 2224/29116; H01L 2224/2912; H01L 2224/29139; H01L 2224/29147; H01L 2224/32245; H01L 2224/48245; H01L 2224/73265; H01L 2224/83447

(57) ABSTRACT

A semiconductor device includes a die pad, a semiconductor element which is disposed on the die pad, an element joining layer which is formed between the die pad and the semiconductor element and joins the semiconductor element to the die pad, a sealing resin which covers the die pad, the semiconductor element, and the element joining layer, and a barrier layer which is formed at a boundary portion between the sealing resin and the element joining layer and blocks corrosive ions derived from the sealing resin. The sealing resin may have an end surface which forms a peripheral outer shape of the sealing resin, and the die pad may include a protruding portion which protrudes outside the sealing resin, with the end surface of the sealing resin given as a starting point.

### RELATED APPLICATIONS

The present application is a continuation application of PCT Application No. PCT/JP2022/035719, filed on Sep. 26, 2022, which corresponds to Japanese Patent Application No. 2021-168410 filed on Oct. 13, 2021 with the Japan Patent Office, and the entire disclosure of this application is incorporated herein by reference.

### TECHNICAL FIELD

The present disclosure relates to a semiconductor device.

### BACKGROUND ART

For example, Japanese Patent Application Publication No. 2017-050441 discloses a semiconductor device which is provided with a semiconductor element in which an electrode pad is formed at a principal surface of the element, an intermediate terminal which is loaded with the semiconductor element and is also conductive with a rear surface of the element, a lateral terminal which is disposed so as to be adjacent to the intermediate terminal and be conductive with the electrode pad, a metal plate which connects the electrode pad to the lateral terminal, a joining layer which is interposed between the electrode pad and the metal plate, and a sealing resin which covers the semiconductor element, in which the metal plate has an element connecting portion that is connected to the electrode pad, a terminal connecting portion that is connected to the lateral terminal, and an intermediate portion that is positioned between the element connecting portion and the terminal connecting portion, and a protrusion is formed at the element connecting portion.

### BRIEF DESCRIPTION OF DRAWINGS

FIG. 1 is a schematic perspective view of a semiconductor device according to an embodiment of the present disclosure.

FIG. 2 is a schematic front elevation view of the semiconductor device.

FIG. 3 is a schematic side view of the semiconductor device

FIG. 4 is a schematic back view of the semiconductor device.

FIG. 5 is a schematic bottom view of the semiconductor device.

FIG. 6 is a view which shows a cross section taken along line VI-VI shown in FIG. 2.

FIG. 7 is an enlarged view of a portion which is surrounded by an alternate long and two short dashed line VII shown in FIG. 6.

FIG. 8 is an enlarged view of a portion which is surrounded by an alternate long and two short dashed line VIII shown in FIG. 7.

FIG. 9 is a flow chart of a manufacturing process of the semiconductor device.

FIG. 10 is a view for describing occurrence of corrosive ions.

FIG. 11A is an SEM image which shows a main portion of a semiconductor device according to Sample 1.

FIG. 11B is an enlarged view of a portion which is surrounded by an alternate long and two short dashed line XIB shown in FIG. 11A.

FIG. 12A is an SEM image which shows a main portion of a semiconductor device according to Sample 2.

FIG. 12B is an enlarged view of a portion which is surrounded by an alternate long and two short dashed line XIIB shown in FIG. 12A.

FIG. 13 is an SEM image for describing a barrier layer of the semiconductor device according to Sample 2.

FIG. 14 is an SEM image for describing the barrier layer of the semiconductor device according to Sample 2.

FIG. 15 is a graph which shows a relationship between the number of cycles and the rate of change in heat resistance in a temperature cycle test.

### DESCRIPTION OF EMBODIMENTS

Next, an embodiment of the present disclosure will be described in detail with reference to the attached drawings.

### [Constitution of Semiconductor Device 1]

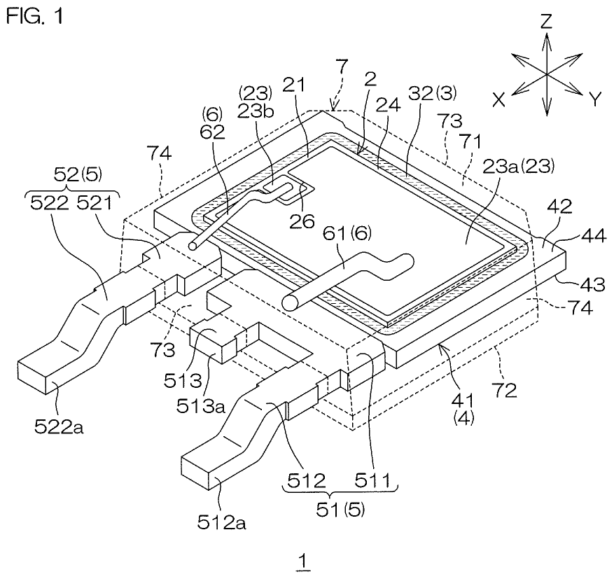

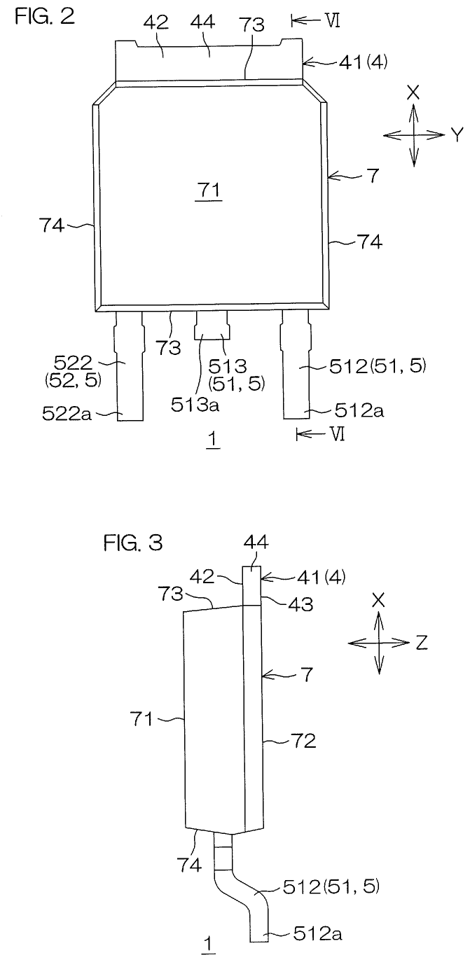

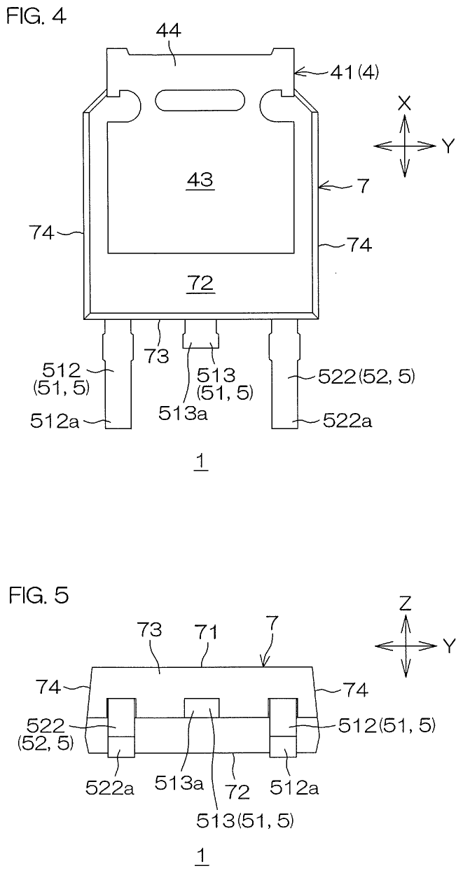

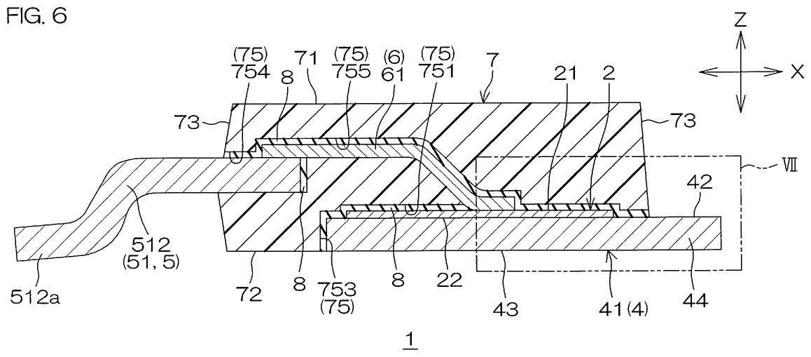

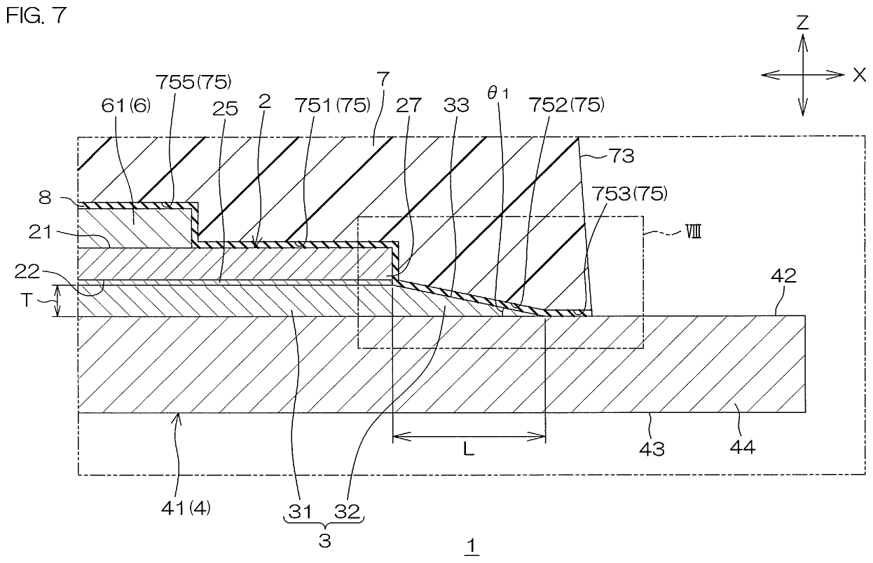

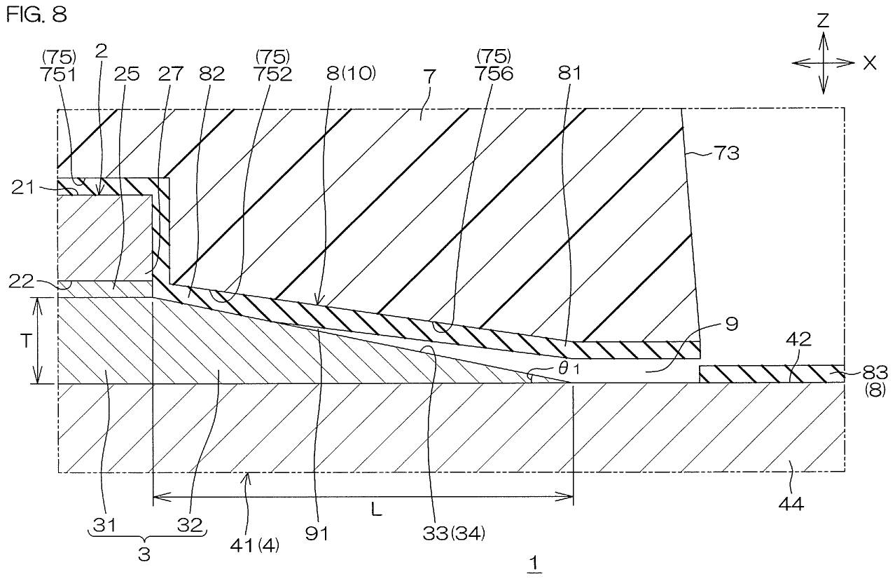

First, with reference to FIG. 1 to FIG. 8, description will be given of a structure of a semiconductor device 1 according to an embodiment of the present disclosure. FIG. 1 is a schematic perspective view of the semiconductor device 1 according to the embodiment of the present disclosure. For clarification, in FIG. 1, a sealing resin 7 which will be described later is shown by broken lines, and an inner structure of the semiconductor device 1 is shown in a perspective manner. FIG. 2 is a schematic front elevation view of the semiconductor device 1. FIG. 3 is a schematic side view of the semiconductor device 1. FIG. 4 is a schematic back view of the semiconductor device 1. FIG. is a schematic bottom view of the semiconductor device 1. FIG. 6 is a view which shows a cross section taken along line VI-VI shown in FIG. 2. FIG. 7 is an enlarged view of a portion which is surrounded by an alternate long and two short dashed line VII shown in FIG. 6. FIG. 8 is an enlarged view of a portion which is surrounded by an alternate long and two short dashed line VIII shown in FIG. 7.

In the following description, an up/down direction of the plan view (FIG. 2) is defined as a first direction X, while a lateral direction of the plan view (FIG. 2) that is at a right angle with respect to the first direction X is defined as a second direction Y. The first direction X and the second direction Y are both at a right angle with respect to a thickness direction (third direction Z) of the semiconductor device 1 and that of a semiconductor element 2 which will be described later, etc.

The semiconductor device 1 is, for example, such a type that is surface-mounted on a circuit substrate of an automotive electrical component, etc. The semiconductor device 1 includes the semiconductor element 2, an element joining layer 3, a pad terminal 4, a lead terminal 5, a bonding wire 6, the sealing resin 7, and a barrier layer 8.

The semiconductor element 2 is an element (semiconductor chip) which serves as a core function of the semiconductor device 1. In this embodiment, the semiconductor element 2 is a discrete element (single-function semiconductor) of a power MOSFET. The semiconductor element 2 is formed, for example, in a quadrilateral shape, one side of which is not less than 3.0 mm and not more than 8.0 mm. The semiconductor element 2 has an element principal surface 21 (first principal surface), an element rear surface 22 (second principal surface), an electrode pad 23, a passivation film 24, and a rear surface electrode 25.

The element principal surface 21 is an upper surface of the semiconductor element 2 shown in FIG. 6 to FIG. 8. With reference to FIG. 1, the electrode pad 23 is formed in the element principal surface 21. The element rear surface 22 is a lower surface of the semiconductor element 2 shown in FIG. 6 to FIG. 8. With reference to FIG. 7 and FIG. 8, the rear surface electrode 25 is formed in the element rear surface 22. In this embodiment, the rear surface electrode 25 acts as a drain electrode of the semiconductor element 2. The element principal surface 21 and the element rear surface 22 are both orthogonal to the thickness direction Z of the semiconductor element 2 and face opposite sides to each other.

With reference to FIG. 1, the electrode pad 23 includes a first electrode pad 23a and a second electrode pad 23b. The electrode pad 23 may be formed of a metal which includes, for example, Al. The electrode pad 23 may be formed of a metal which includes, for example, an Al—Cu alloy, an Al—Si alloy, an Al—Si—Cu alloy, etc. Specifically, the electrode pad 23 may be a pad which is made of a laminated structure of Al—Cu/Ti. In this embodiment, the first electrode pad 23a is a source electrode of the semiconductor element 2. In this embodiment, the second electrode pad 23b is a gate electrode of the semiconductor element 2. The first electrode pad 23a is formed substantially in a quadrilateral shape which covers almost an entirety of the element principal surface 21. The second electrode pad 23b is formed at a recessed portion 26 which is formed at one side of the first electrode pad 23a. Therefore, an area of the first electrode pad 23a is to be larger than that of the second electrode pad 23b. The bonding wire 6 is connected to the first electrode pad 23a and the second electrode pad 23b.

With reference to FIG. 1, the passivation film 24 is a protective film of the semiconductor element 2 which is formed so as to cover the element principal surface 21. The passivation film 24 may be such that an Si₃N₄ layer which is formed, for example, by a plasma CVD method and a polyimide resin layer which is formed by coating are laminated to each other. The first electrode pad 23a and the second electrode pad 23b are both exposed from the passivation film 24.

With reference to FIG. 1, FIG. 7, and FIG. 8, the element joining layer 3 is an electroconductive member which is interposed between the semiconductor element 2 and the pad terminal 4. The semiconductor element 2 is loaded on the pad terminal 4 by a die bonding with use of the element joining layer 3, and conductivity between the semiconductor element 2 and the pad terminal 4 is secured. The element joining layer 3 is made of, for example, a solder alloy material, an Ag sintered material, etc.

Examples of the solder alloy material that can be mentioned include a high-temperature solder (high-temperature solder having a solidus temperature of, for example, not less than about 268° C. and not more than about 305° C.). The high-temperature solder is such that, for example, Pb or Sn is used as a base material, and Ag, Sb, In, etc., may be incorporated in the base material. The solder may contain, for example, Pb of not less than 85 wt % and Sn of not more than 10 wt % and it may be, to be specific, Pb-5Sn, Pb-2Sn-2.5Ag. Further, as a high-temperature Pb-free solder, a SAC-based solder which is Sn—Ag—Cu may be used. Of these solder materials, in this embodiment in which the semiconductor element 2 is a power MOSFET (power semiconductor), the high-temperature solder is preferably used. Where the element joining layer 3 is the high-temperature solder, it is able to resist a relatively high temperature arising from the power MOSFET. Further, when the semiconductor device 1 which is of a surface mount type is mounted on an external circuit substrate, it is necessary to conduct reflow processing (for example, reflow processing at about 260° C. by using a SAC-based solder) again. Where the layer is the high-temperature solder, it is possible to prevent the element joining layer 3 from melting upon this reflow processing.

The pad terminal 4 is an electroconductive member which is joined to a circuit substrate, thereby constituting a conductive channel of the semiconductor device 1 with the circuit substrate. In this embodiment, the pad terminal 4 includes a die pad 41. Hereinafter, unless otherwise specified, the pad terminal 4 will be described as the die pad 41. In this embodiment, the die pad 41 is made of an alloy which contains Cu. Further, in this embodiment, the die pad 41 has a thickness which is, for example, not less than 1.0 mm and not more than 2.0 mm. If the die pad 41 has a thickness of not less than 1.0 mm and not more than 2.0 mm, the die pad 41 can be made relatively low in heat resistance. Thereby, the semiconductor device 1 can be improved in heat dissipation.

With reference to FIG. 1 and FIG. 6 to FIG. 8, the die pad 41 is a portion at which the semiconductor element 2 is loaded. The die pad 41 has a loading surface 42 and a mounting surface 43. The loading surface 42 is a surface on which the semiconductor element 2 is loaded, and the mounting surface 43 is a surface which faces the opposite side in relation to the loading surface 42. The loading surface 42 is an upper surface of the die pad 41 shown in FIG. 6 to FIG. 8. The mounting surface 43 is a lower surface of the die pad 41 shown in FIG. 6 to FIG. 8. The loading surface 42 and the mounting surface 43 are both flat. The loading surface 42 and the mounting surface 43 may be both covered with an exterior plating layer. The exterior plating layer serves such a function that when the semiconductor device 1 is surface-mounted on a circuit substrate by solder joint through reflow processing, a solder adheres well to a portion of the pad terminal 4 which is exposed from the sealing resin 7, thereby preventing the portion from erosion caused by the solder joint.

With reference to FIG. 7 and FIG. 8, the above-described element joining layer 3 is interposed between the element rear surface 22 (rear surface electrode 25) and the loading surface 42, and the die pad 41 is conductive with the rear surface electrode 25 via the element joining layer 3. Therefore, the die pad 41 (pad terminal 4) functions as a drain terminal of the semiconductor device 1. Further, as shown in FIG. 1 to FIG. 4, a part of the loading surface 42 and the mounting surface 43 are both exposed from the sealing resin 7. In the die pad 41, a portion which protrudes from an end surface of the sealing resin 7 (a resin first side surface 73 which will be described later) may be referred to as a protruding portion 44 of the die pad 41.

Here, with reference to FIG. 1, FIG. 7, and FIG. 8, the element joining layer 3 includes integrally a main body portion 31 which is held between the die pad 41 and the semiconductor element 2 and a peripheral portion 32 which is formed around the semiconductor element 2. The main body portion 31 constitutes a main channel of a conductive channel which is also a heat dissipation channel between the die pad 41 and the rear surface electrode 25 in the element joining layer 3. The peripheral portion 32 may be an excess portion of a solder material which oozes outside the semiconductor element 2 when the semiconductor element 2 is loaded on the die pad 41 by solder joint through reflow processing. The peripheral portion 32 surrounds the semiconductor element 2. The peripheral portion 32 constitutes a sub-channel of the conductive channel which is also the heat dissipation channel. Due to formation of the peripheral portion 32, heat generated in the semiconductor element 2 is prevented from staying directly under the semiconductor element 2 and can be spread widely around the semiconductor element 2. Thereby, the semiconductor device 1 can be improved in heat dissipation. It is noted that the element joining layer 3 may be free of the peripheral portion 32 and constituted only of the main body portion 31. The peripheral portion 32 may be partially wetted up onto an end surface of the semiconductor element 2.

With reference to FIG. 7 and FIG. 8, the peripheral portion 32 of the element joining layer 3 has an inclined surface 33 which is inclined with respect to the loading surface 42 of the die pad 41. The inclined surface 33 is inclined downward toward the loading surface 42 from the vicinity of a lower edge corner 27 of the semiconductor element 2. The inclined surface 33 is flat and inclined at an angle θ₁ of, for example, not less than 5° and not more than 45° with respect to the loading surface 42. It is noted that the peripheral portion 32 may have a curved side surface 34 which extends from the vicinity of the lower edge corner 27 of the semiconductor element 2 to the loading surface 42, instead of the flat inclined surface 33. Further, the peripheral portion 32 may have a length L of not less than 0.1 mm and not more than 2 mm in relation to the thickness T of the element joining layer 3 (for example, not less than 50 μm and not more than 200 μm).

The lead terminal 5 is an electroconductive member which is joined to a circuit substrate, thereby constituting a conductive channel of the semiconductor device 1 with the circuit substrate. With reference to FIG. 1, the lead terminal 5 is disposed so as to be adjacent to the pad terminal 4 in the first direction X and be conductive with the electrode pad 23. With reference to FIG. 1, FIG. 2, FIG. 4, and FIG. 5, the lead terminal 5 includes a first lead terminal 51 and a second lead terminal 52 which are adjacent to each other in the second direction Y in a plan view. In this embodiment, the lead terminal 5 is made of an alloy that contains Cu, as with the pad terminal 4. Further, in this embodiment, the lead terminal 5 has a thickness of, for example, not less than 1.0 mm and not more than 2.0 mm.

With reference to FIG. 1 and FIG. 6, the bonding wire 6 is connected to the first lead terminal 51. The first lead terminal 51 is conductive with the first electrode pad 23a via the bonding wire 6. Therefore, the first lead terminal 51 is a source terminal of the semiconductor device 1. The first lead terminal 51 has a first pad portion 511, a first lead portion 512, and a dummy lead portion 513.

With reference to FIG. 1, the first pad portion 511 is a portion showing substantially a quadrilateral shape in a plan view to which the bonding wire 6 is connected. The first pad portion 511 is flat and covered with the sealing resin 7 in its entirety. The first lead portion 512 is a portion showing substantially a quadrilateral shape in a plan view which is disposed so as to continue to the first pad portion 511 and be parallel to the first direction X. The first lead portion 512 has a portion which is exposed from the sealing resin 7. With reference to FIG. 1, FIG. 3, and FIG. 6, the exposed portion of the first lead portion 512 is bend-processed in a gull wing shape. A leading end portion 512a of the first lead portion 512 is a portion which is joined to a circuit substrate of the first lead terminal 51. With reference to FIG. 1, the dummy lead portion 513 is a portion showing substantially a quadrilateral shape in a plan view which is disposed so as to continue to the first pad portion 511 and be parallel to the first direction X. The dummy lead portion 513 extends, from the first pad portion 511, in parallel to the first lead portion 512 in the first direction X. Therefore, the first lead portion 512 and the dummy lead portion 513 are adjacent to each other in the second direction Y. The dummy lead portion 513 has a portion which is exposed from the sealing resin 7. The exposed portion of the dummy lead portion 513 is in a flat plate shape. Therefore, a leading end portion 513a of the dummy lead portion 513 is positioned above in the third direction Z in relation to the leading end portion 512a of the first lead portion 512. Thereby, when the semiconductor device 1 is mounted on the circuit substrate, the dummy lead portion 513 is not in contact with the circuit substrate and supported by the sealing resin 7 in a cantilever manner.

With reference to FIG. 1, the bonding wire 6 is connected to the second lead terminal 52. The second lead terminal 52 is conductive with the second electrode pad 23b via the bonding wire 6. Therefore, the second lead terminal 52 is a gate terminal of the semiconductor device 1. The second lead terminal 52 has a second pad portion 521 and a second lead portion 522.

With reference to FIG. 1, the second pad portion 521 is a portion showing substantially a quadrilateral shape in a plan view to which the bonding wire 6 is connected. The second pad portion 521 is flat and covered with the sealing resin 7 in its entirety. The second lead portion 522 is a portion showing substantially a quadrilateral shape in a plan view which is disposed so as to continue to the second pad portion 521 and be parallel to the first direction X. The second lead portion 522 has a portion which is exposed from the sealing resin 7. With reference to FIG. 1, the exposed portion of the second lead portion 522 is bend-processed in a gull wing shape. In this embodiment, the shape of the second lead portion 522 is the same as that of the first lead portion 512. A leading end portion 522a of the second lead portion 522 is a portion which is joined to a circuit substrate of the second lead terminal 52.

The bonding wire 6 includes a first bonding wire 61 and a second bonding wire 62. With reference to FIG. 1, the first bonding wire 61 is an electroconductive member which connects the first electrode pad 23a with the first pad portion 511 of the first lead terminal 51. Therefore, the first bonding wire 61 is a source wire of the semiconductor device 1. In this embodiment, the first bonding wire 61 is made with, for example, Al or an Al alloy. The first bonding wire 61 has a diameter of, for example, not less than 250 μm and not more than 500 μm. The second bonding wire 62 is an electroconductive member which connects the second electrode pad 23b with the second pad portion 521 of the second lead terminal 52. Therefore, the second bonding wire 62 is a gate wire of the semiconductor device 1. In this embodiment, the second bonding wire 62 is made with, for example, Al or an Al alloy. The second bonding wire 62 is thinner than the first bonding wire 61 and has a diameter of, for example, not less than 100 μm and not more than 200 μm.

The sealing resin 7 is made of a black resin having electric insulation. The sealing resin 7 may, for example, has a thermosetting resin such as an epoxy resin given as a matrix resin (base resin) and may contain a filling material, a silane coupling agent as an additive, a hardening agent, a hardening accelerator, etc. Examples of the filling material that can be mentioned include a silica filler, talc, clay, glass beads, a glass fiber, etc. The silane coupling agent has a function of improving adhesion of an organic surface of, for example, the sealing resin 7 with inorganic surfaces of glass, metal and others. Examples of the hardening agent that can be mentioned include an amine-based hardening agent, an acid anhydride-based hardening agent, a phenol resin, an amino resin, etc. Examples of the hardening accelerator that can be mentioned include a phosphorus-based hardening accelerator, a tertiary amine-based hardening accelerator, an imidazole-based hardening accelerator, etc. In this embodiment, the phosphorus-based hardening accelerator is used.

The sealing resin 7 covers a part of each of the pad terminal 4 and the lead terminal 5 as well as the semiconductor element 2 and the bonding wire 6. The sealing resin 7 is formed by transfer molding with use of a metal die. The sealing resin 7 has a resin principal surface 71, a resin rear surface 72, a resin first side surface 73, a resin second side surface 74, and a resin inner surface 75.

The resin principal surface 71 is an upper surface of the sealing resin 7 shown in FIG. 5 and FIG. 6. The resin rear surface 72 is a lower surface of the sealing resin 7 shown in FIG. 5 and FIG. 6. The resin principal surface 71 and the resin rear surface 72 are both orthogonal to the thickness direction Z of the semiconductor device 1 and face opposite sides to each other. In this embodiment, the mounting surface 43 is exposed from the resin rear surface 72.

With reference to FIG. 2, the resin first side surface 73 is constituted of a pair of surfaces which are formed with separation in the first direction X. The pair of resin first side surfaces 73 face opposite sides to each other. An upper end of the resin first side surface 73 continues to the resin principal surface 71 and a lower end of the resin first side surface 73 continues to the resin rear surface 72. In this embodiment, as shown in FIG. 1, a part of the first lead terminal 51 and a part of the second lead terminal 52 are exposed from one of the resin first side surfaces 73. Further, with reference to FIG. 2 to FIG. 4, the protruding portion 44 of the die pad 41 is exposed from the other of the resin first side surfaces 73.

With reference to FIG. 2, the resin second side surface 74 is constituted of a pair of surfaces which are formed with separation in the second direction Y. The pair of resin second side surfaces 74 face opposite sides to each other. An upper end of the resin second side surface 74 continues to the resin principal surface 71 and a lower end of the resin second side surface 74 continues to the resin rear surface 72. Unlike the resin first side surface 73, the pad terminal 4 or the lead terminal 5 is not exposed from the resin second side surface 74.

The resin inner surface 75 may be either of a surface in which the sealing resin 7 is in contact with an inner structure covered with the sealing resin 7 and a surface in which it faces the inner structure via a space such as a gap 9 which will be described later. Here, the surface in which it is in contact with the inner structure broadly encompasses a case where a space such as the gap is not formed with the inner structure and may include both a surface in which it is directly in contact with the inner structure and a surface in which it is indirectly in contact therewith by interposing an intermediate layer such as the barrier layer 8.

With reference to FIG. 6 to FIG. 8, the resin inner surface 75 may include a first inner surface 751 which is a contact surface of the sealing resin 7 with the semiconductor element 2, a second inner surface 752 which is a contact surface of the sealing resin 7 with the element joining layer 3, a third inner surface 753 which is a contact surface of the sealing resin 7 with the pad terminal 4 (die pad 41), a fourth inner surface 754 which is a contact surface of the sealing resin 7 with the lead terminal 5, and a fifth inner surface 755 which is a contact surface of the sealing resin 7 with the bonding wire 6.

On the other hand, with reference to FIG. 8, a gap 9 which extends from an end surface of the sealing resin 7 (in this embodiment, the resin first side surface 73 on which the protruding portion 44 is formed) toward the semiconductor element 2 may be formed in the semiconductor device 1. In this embodiment, the gap 9 extends so as to bend upward from the resin first side surface 73 of the sealing resin 7 along the loading surface 42 of the die pad 41 and the inclined surface 33 of the element joining layer 3 in a cross sectional view and has a leading end portion 91 in the inclined surface 33 of the element joining layer 3. The leading end portion 91 corresponds to a dead end of the gap 9, when the resin first side surface 73 of the sealing resin 7 is given as an entrance of the gap 9. The resin inner surface 75 which faces the die pad 41 and the element joining layer 3 via the gap 9 may be a sixth inner surface 756. The sixth inner surface 756 is separated from the die pad 41 and the element joining layer 3 across the gap 9. Therefore, on the inclined surface 33 of the element joining layer 3, a portion from the lower edge corner 27 of the semiconductor element 2 to a midway point of the inclined surface 33 is the second inner surface 752, and a portion from the midway point of the inclined surface 33 to the loading surface 42 of the die pad 41 is the sixth inner surface 756.

With regard to the resin inner surface 75, the surfaces which are in contact with an inner structures such as the semiconductor element 2 and the die pad 41 inside the sealing resin 7 (in this embodiment, the first to fifth inner surfaces 751 to 755) may be collectively defined as a resin inner contact surface, and the surfaces which are separated from the inner structure via a space such as the gap 9 (in this embodiment, the sixth inner surface 756) may be collectively defined as a resin inner separation surface.

The barrier layer 8 is made of a material having a function of blocking corrosive ions derived from the sealing resin 7 from coming into contact with the element joining layer 3. The corrosive ions are ions which can cause corrosion by attacking the element joining layer 3. In this embodiment, ions which are primarily contained in the sealing resin 7 and ions which are generated by a chemical change or denaturation of a constituent material of the sealing resin 7 can be mentioned. Specifically, SiO₃H ions derived from a silane coupling agent, PO₃ ions derived from a phosphorus-based hardening accelerator, and COOH ions generated by oxidation of an epoxy resin, etc. can be mentioned. Where these ions are present, there may be a case that a constituent material of the element joining layer 3 easily undergoes ionization (for example, ionization of Pb into Pb ions, etc.) and the element joining layer 3 undergoes electrochemical corrosion, thereby developing a void or a crack in the element joining layer 3.

Specific examples of the barrier layer 8 for preventing this type of void or crack that can be mentioned include aluminum oxide (Al₂O₃), silicon oxide (SiO₂), zirconium oxide (ZrO₂), tantalum pentoxide (Ta₂O₅), hafnium dioxide (HfO₂), yttrium oxide (Y₂O₃), and a multi-layered structure of these. Of these materials, Al₂O₃ is used in this embodiment. Further, the barrier layer 8 may have a thickness of not less than 50 nm and not more than 10 μm.

With reference to FIG. 6 to FIG. 8, the barrier layer 8 is formed so as to generally cover the inner structures of the semiconductor element 2, the element joining layer 3, the pad terminal 4 (die pad 41), the lead terminal 5, the bonding wire 6, etc. inside the sealing resin 7. Therefore, inside the sealing resin 7, the upper surfaces and the side surfaces of the semiconductor element 2, the pad terminal 4 (die pad 41), the element joining layer 3, and the lead terminal 5 shown in FIG. 6 to FIG. 8 are covered with the barrier layer 8. On the other hand, the barrier layer 8 does not cover the protruding portion 44 of the die pad 41 or an exposed portion of the lead terminal 5 outside the sealing resin 7. Thereby an electroconductive terminal surface for securing conductivity with a circuit substrate is provided at a portion outside the pad terminal 4 (die pad 41) and the sealing resin 7 of the lead terminal 5.

With reference to FIG. 8, the barrier layer 8 forms the boundary portion 10 between the element joining layer 3 (peripheral portion 32) and the sealing resin 7. A part of the barrier layer 8 is held so as to be in close contact with the resin inner surface 75 of the sealing resin 7 in a state of floating from the die pad 41 via the gap 9. The barrier layer 8 may include, for example, a separation portion 81 in a state of floating from the die pad 41 and the element joining layer 3 via the gap 9 and a holding portion 82 which is held between the sealing resin 7 and the element joining layer 3 at a portion between the lower edge corner 27 of the semiconductor element 2 and the leading end portion 91 of the gap 9. Further, the barrier layer 8 on the loading surface 42 outside the sealing resin 7 may be an outer barrier layer 83 which is separated from the barrier layer 8 (separation portion 81) in close contact with the resin inner surface 75, with the vicinity of the resin first side surface 73 given as a boundary.

### [Method for Manufacturing Semiconductor Device 1]

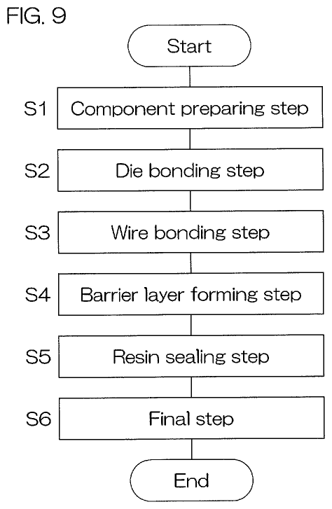

Next, description will be given of a method for manufacturing the semiconductor device 1. FIG. 9 is a flow chart which shows an example of a manufacturing process of the semiconductor device 1.

With reference to FIG. 9, the method for manufacturing the semiconductor device 1 may include mainly a component preparing step S1, a die bonding step S2, a wire bonding step S3, a barrier layer forming step S4, a resin sealing step S5, and a final step S6. The method for manufacturing the semiconductor device 1 may include a step which is not shown in FIG. 9.

The component preparing step S1 is a step for preparing individual constituents of the above-described semiconductor device 1. For example, from a wafer of the semiconductor element 2, the semiconductor element 2 having a predetermined size is produced by dicing the wafer. Further, a lead frame in which the pad terminal 4 (die pad 41) and the lead terminal 5 are connected integrally is formed by metal-die molding.

The die bonding step S2 is a step in which the semiconductor element 2 is subjected to die bonding. The die bonding step S2 is conducted, for example, by using a well-known die bonder and may be referred to as a mount step. The die bonding step S2 is a step in which the semiconductor element 2 is joined to the die pad 41 by the element joining layer 3 so as to be conductive therewith. Specifically, a bonding material in a paste form (for example, solder paste, Ag paste, etc.) is coated on the loading surface 42 of the die pad 41, and the semiconductor element 2 is placed via the bonding material. Then, an ambient temperature inside a furnace is raised to a melting point of the bonding material or higher (for example, not less than 300° C. and not more than 390° C. for a high-temperature solder), thereby melting the bonding material. Thereafter, the ambient temperature inside the furnace is lowered to a normal temperature (a temperature lower than the melting point of the bonding material), and the bonding material is cured to form the element joining layer 3. Thereby, the semiconductor element 2 is joined to the die pad 41 so as to be conductive therewith.

The wire bonding step S3 is a step in which the first bonding wire 61 and the second bonding wire 62 are subjected to bonding. The wire bonding step S3 is conducted by using, for example, a well-known wire bonder. The wire bonding step S3 includes a step in which one end of the first bonding wire 61 is subjected to wire bonding with the first electrode pad 23a and the other end of the first bonding wire 61 is subjected to wire bonding with the first pad portion 511, by using the wire bonder. Specifically, first, a leading end portion of a wire is allowed to protrude from a capillary of the wire bonder and melted, then, the leading end portion of the wire is shaped into a ball form. Then, the leading end portion is pressed against the first electrode pad 23a. Next, while the wire is drawn out from the capillary, the capillary is moved and the wire is pressed against the first pad portion 511. Then, while the wire is pressed by using a clamper of the capillary, the capillary is brought up and the wire is cut out. Thereby, the first bonding wire 61 is formed, and the first electrode pad 23a is connected so as to be conductive with the first pad portion 511. The wire bonding step S3 includes a step in which one end of the second bonding wire 62 is subjected to wire bonding with the second electrode pad 23b and the other end of the second bonding wire 62 is subjected to wire bonding with the second pad portion 521, by using the wire bonder according to the same method.

In this embodiment, all wire joining portions may be processed by wedge bonding. In the wedge bonding, the portions are formed by pressing a wire against a predetermined position and cutting the wire. For the sake of convenience, according to a sequence of joining the wire, the respective wire joining portions may be distinguished between those to be processed by a first bonding and those to be processed by a second bonding. In the wire bonding step S3, the first electrode pad 23a and the second electrode pad 23b are processed by the first bonding, and the first pad portion 511 and the second pad portion 521 are processed by the second bonding. It is noted that the first bonding may be applied to the first pad portion 511 and the second pad portion 521, and the second bonding may be applied to the first electrode pad 23a and the second electrode pad 23b.

The barrier layer forming step S4 is a step in which the semiconductor element 2, the element joining layer 3, the pad terminal 4 (die pad 41), the lead terminal 5, and the bonding wire 6 are covered with the barrier layer 8. The barrier layer forming step S4 is conducted, for example, by a well-known film forming method. In this embodiment, an Al₂O₃ film is formed by using an ion plating method or a sputtering method, etc. A temperature at which the barrier layer 8 is formed may be, for example, not less than a room temperature and not more than 300° C.

The resin sealing step S5 is a step in which the sealing resin 7 is formed and the semiconductor device 1 is packaged. That is, the resin sealing step S5 is a step for forming the sealing resin 7 having the above-described shape. The resin sealing step S5 is conducted, for example, by a well-known transfer molding with use of a metal die. Specifically, after formation of the barrier layer 8, a lead frame in which the semiconductor element 2 has been subjected to bonding is set at a metal-die molding machine and a fluidized epoxy resin is allowed to flow into the metal die, thereby performing a mold forming. Then, the epoxy resin is cured and the molded lead frame is taken out. Then, the lead frame is formed into a shape of the above-described sealing resin 7 by removing an excessive resin or performing deburring.

The final step S6 is a step in which the semiconductor device 1 is formed into a shape shown in FIG. 1 and the semiconductor device 1 is made into a product which is ready for shipment. The final step S6 includes, for example, a step for deburring the sealing resin 7, a cutting step for cutting an unnecessary portion of the lead frame exposed outside the sealing resin 7, an exterior treatment step for improving a strength against bending of the lead frame exposed outside the sealing resin 7, improving solder wettability at the time of mounting on a circuit substrate, etc. and preventing rust, a cleaning step prior to the exterior treatment step, a lead processing step for bending the lead frame exposed outside the sealing resin 7 into a predetermined shape, a seal-affixing step for printing a company name, a product name, a lot number, etc. on a package, an inspection/filtering step for determining pass/failure of the product, and others. These steps may be conducted whenever necessary depending on final specifications of the semiconductor device 1. Further, in the deburring step and the cleaning step, the barrier layer 8 which has been formed on the lead terminal 5 exposed outside the sealing resin 7 is removed and an exterior surface of the lead terminal 5 is exposed. The final step S6 is finished, by which the semiconductor device 1 shown in FIG. 1 is completed.

### [Examination of Occurrence of Corrosive Ions]

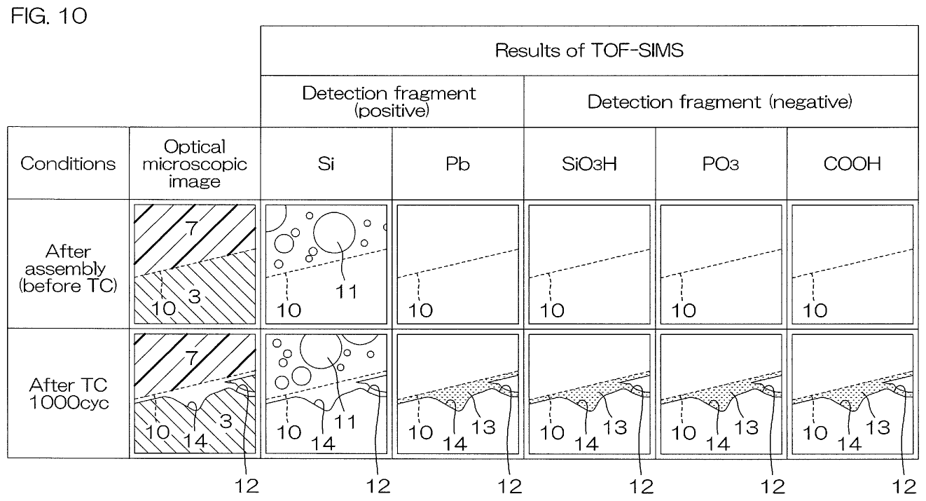

FIG. 10 is a view for examining occurrence of corrosive ions at the boundary portion 10 between the sealing resin 7 and the element joining layer 3. Here, the semiconductor device according to Sample 1 having a structure which is free of the barrier layer 8 of the above-described semiconductor device 1 is to be observed. FIG. 10 represents optical microscopic images of the boundary portion 10 between the sealing resin 7 and the element joining layer 3 in Sample 1 and analysis result images by TOF-SIMS (Time-of-Flight Secondary Ion Mass Spectrometry) by using diagrammatic drawings. In Sample 1, the sealing resin 7 is an epoxy resin which contains at least a silane coupling agent and a phosphorus-based hardening accelerator as additives as well as a silica filler as a filling material 11. The element joining layer 3 is a high-temperature solder which is made up of Pb-2Sn-2.5Ag.

In FIG. 10, the left-most squares are drawings which correspond to the optical microscopic image and squares other than them are drawings in which analysis results of the TOF-SIMS are shown for each of detection fragments including those of an Si ion, Pb ion, SiO₃H ion, PO₃ ion and COOH ion. While all the drawings of the respective detection fragments show analysis results at the boundary portion 10, as with the optical microscopic image, reference signs of the sealing resin 7 and the element joining layer 3 are omitted for clarification.

Further, in FIG. 10, the respective drawings at the upper row are those after assembly of the semiconductor device of Sample 1 (immediately after manufacture), showing conditions before execution of the temperature cycle test (TC). On the other hand, the respective drawings at the lower row show conditions after execution of the temperature cycle test (TC) in the semiconductor device of Sample 1. The temperature cycle test is executed by raising and lowering the temperature of the semiconductor device after assembly between −55° C. and 150° C. repeatedly at 1000 cycles after execution of a prior-processing test in which the semiconductor device is exposed to an environment of MSL1 (Moisture Sensitivity Level 1) in accordance with IPC/JEDEC J-STD-020.

As a result, with reference to the optical microscopic drawings at the lower row, it has been confirmed that corrosion occurred in the element joining layer 3, and a void 14 and a crack 12 occurred at the element joining layer 3 side in relation to the boundary portion 10. As the result of an additional examination, it has been found that occurrence of the void 14 and the crack 12 is influenced by a thermal stress (tensile stress) occurring at the boundary portion 10 at the time of the temperature cycle test and is also involved with corrosive actions by corrosive ions (corrosive chemical species) occurring at the boundary portion 10.

For example, with reference to squares corresponding to Pb ions, SiO₃H ions, PO₃ ions, and COOH ions at the lower row in FIG. 10, dot hatching is given to a distribution region 13 in which distribution of the respective ions has been confirmed by the TOF-SIMS. From these squares, it has been confirmed that SiO₃H ions, PO₃ ions, and COOH ions which are corrosive ions are widely distributed in a region where the void 14 and the crack 12 occurred, thereby resulting in progress of corrosion by ionization of Pb of the high-temperature solder. It is considered that, for example, the SiO₃H ions are derived from a silane coupling agent contained in the sealing resin 7, the PO₃ ions are derived from a phosphorus-based hardening accelerator in the sealing resin 7, and the COOH ions are generated by oxidation of an epoxy resin of the sealing resin 7. That is, it is considered that under conditions where the void 14 and the crack 12 are likely to occur by a thermal stress at the time of the temperature cycle test, the generation of corrosive ions at the boundary portion 10 causes the alloy compositions of the element joining layer 3 (solder alloy) to lose balance, resulting in the occurrence of the void 14 and the crack 12 being accelerated.

Although not shown here, a high-temperature Pb solder (Pb solder alloy) having an Sn composition and an Ag composition different from Pb-2Sn-2.5Ag as well as an SAC-based high-temperature Pb-free solder (Pb-free solder alloy) which is Sn—Ag—Cu are also examined in a similar manner, resulting in confirmation that the void 14 and the crack 12 shown in FIG. 10 have occurred. From the above, it is possible to say that cracks resulting from a stress and corrosion may easily occur where the element joining layer 3 is an alloy.

### [Effects of Semiconductor Device 1]

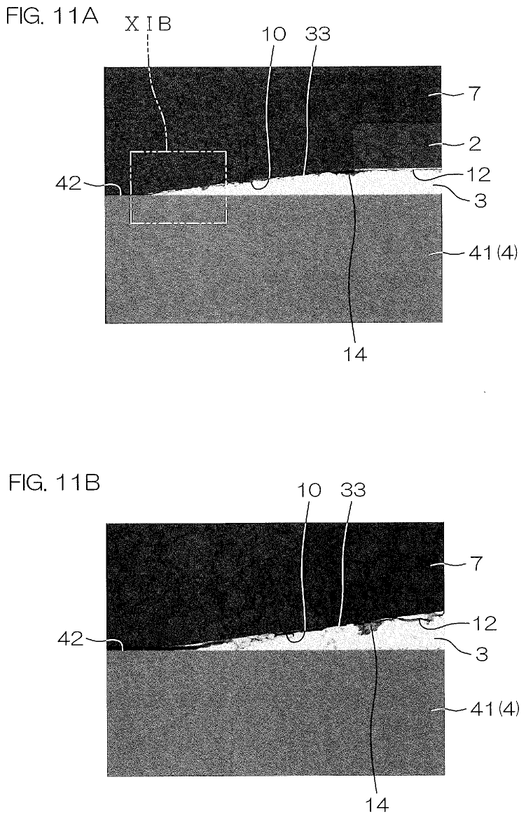

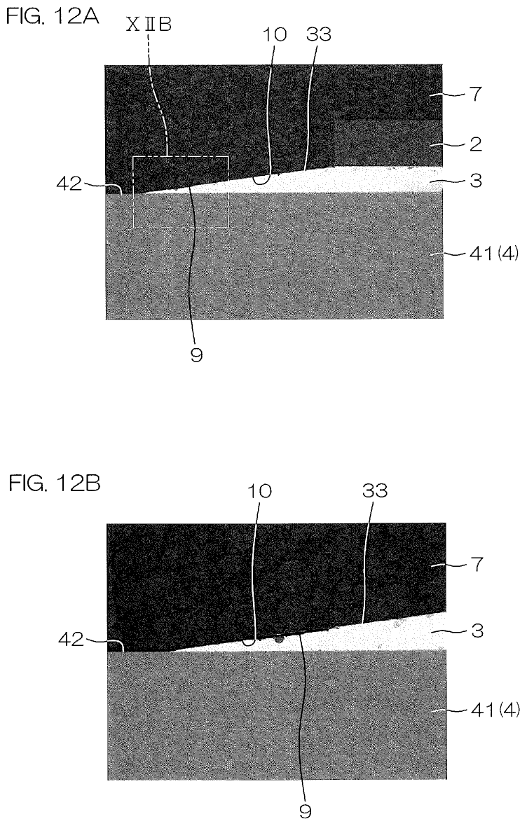

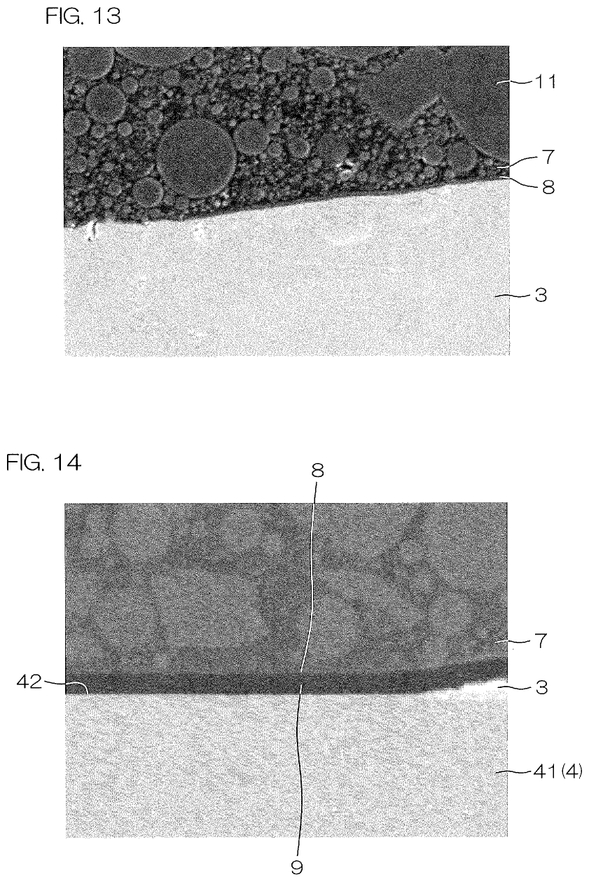

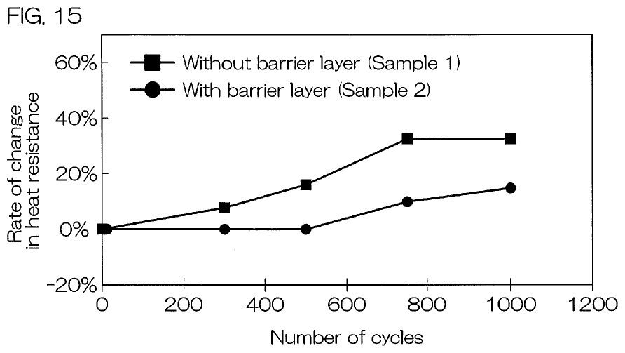

Next, effects of the semiconductor device 1 according to the embodiment of the present disclosure will be described with reference to FIGS. 11A and 11B to FIG. 15. FIG. 11A is an SEM image which shows a main portion of the semiconductor device according to Sample 1. FIG. 11B is an enlarged view of a portion which is surrounded by an alternate long and two short dashed line XIB shown in FIG. 11A. FIG. 12A is an SEM image which shows a main portion of the semiconductor device according to Sample 2. FIG. 12B is an enlarged view of a portion which is surrounded by an alternate long and two short dashed line XIIB shown in FIG. 12A. FIG. 13 is an SEM image for describing the barrier layer 8 of the semiconductor device according to Sample 2. FIG. 14 is an SEM image for describing the barrier layer 8 of the semiconductor device according to Sample 2. FIG. 15 is a graph which shows a relationship between the number of cycles and the rate of change in heat resistance in the temperature cycle test.

In the above description, with reference to FIG. 10, a description has been given of the mechanism of occurrence of the void and the crack in the element joining layer 3 derived from corrosive ions in Sample 1. In Sample 1, since the barrier layer 8 is not provided, the void 14 and the crack 12 have occurred. Hereinafter, suppression of occurrence of the crack 12 by the barrier layer 8 will be described by comparing Sample 1 with Sample 2. Sample 2 which is to be compared with Sample 1 has the same structure as Sample 1 except that the barrier layer 8 (Al₂O₃ layer) is provided between the sealing resin 7; and the die pad 41 (pad terminal 4) and the element joining layer 3. As shown in FIG. 13, in Sample 2, there can be confirmed the barrier layer 8 which is held between the sealing resin 7 and the element joining layer 3. That is, the structure of Sample 2 as a whole is the same as the structure shown in FIG. 1 to FIG. 8.

Then, FIG. 11A and FIG. 11B (Sample 1); and FIG. 12A and FIG. 12B (Sample 2) all show the SEM images obtained after execution of the temperature cycle test at 750 cycles. First, with reference to FIG. 11A and FIG. 11B, since the barrier layer 8 is not formed in Sample 1, the large void 14 and the crack 12 which extends from the void 14 to an interior of the element joining layer 3 have been confirmed at the boundary portion 10 between the sealing resin 7 and the element joining layer 3. The void 14 and the crack 12 are distributed all over the inclined surface 33 of the element joining layer 3, and the crack 12 extends long in the horizontal direction so as to divide the conductive channel and the heat dissipation channel between the semiconductor element 2 and the element joining layer 3 immediately under the semiconductor element 2. Further, although not shown, when the SEM image is observed in a color image, a great change in color has been found at a portion near the boundary portion 10 of the sealing resin 7. This may be due to a fact that the sealing resin 7 is partially oxidized by oxygen and moisture which have infiltrated into the sealing resin 7 through the void 14.

In contrast thereto, with reference to FIG. 12A and FIG. 12B, no noticeable occurrence of the void 14 or the crack 12 has been confirmed even after execution of the temperature cycle test at 750 cycles. On the other hand, the gap 9 resulting from an interfacial peeling is formed between the sealing resin 7 and the element joining layer 3, and the peeling is stopped at a midway point of the inclined surface 33 of the element joining layer 3. Moreover, as shown in FIG. 14, it has been confirmed that at the gap 9, the barrier layer 8 is held so as to be in close contact with a resin inner surface of the sealing resin 7 in a state of floating from the die pad 41 (refer also to FIG. 8). Further, the change in color as found in Sample 1 has not been confirmed in the sealing resin 7 of Sample 2 even after the temperature cycle test.

As described so far, with the semiconductor device 1 according to this embodiment, the barrier layer 8 is formed between the sealing resin 7 and the element joining layer 3, thus making it possible to prevent corrosive ions from coming into contact with the element joining layer 3. It is, thereby, possible to suppress corrosion of the element joining layer 3 and prevent the element joining layer 3 from becoming fragile in terms of strength. As a result, even if a stress is applied to the element joining layer 3, it is possible to suppress occurrence of a crack in the element joining layer 3, thus making it possible to suppress a decrease in heat dissipation via the element joining layer 3.

In particular, since a power semiconductor requires a large current (for example, several dozen A to 100 A) to flow through, it is desirable that an electrical resistance value is kept as low as possible. In order to attain a lower resistance value, various types of members (for example, pad terminal 4, lead terminal 5, bonding wire 6, etc.) which constitute the semiconductor device 1 tend to be large in size, for example, and as a result, a stress which is transferred from these members to the element joining layer 3 will be easily made large. Thus, a crack is more likely to occur in the element joining layer 3 due to the stress. In contrast thereto, according to the semiconductor device 1, it is possible to suppress corrosion of the element joining layer 3 by the barrier layer 8 and prevent the element joining layer 3 from becoming fragile in terms of strength. Therefore, even if a large stress is applied to the element joining layer 3, it is possible to suppress occurrence of a crack in a broad range.

Moreover, the semiconductor device 1 is to be surface-mounted on a circuit substrate, etc. by way of the pad terminal 4 (die pad 41) which is a drain terminal. The semiconductor device 1 which is of a surface mount type is mounted by reflowing a joining material for attachment to the circuit substrate (for example, a paste for attachment such as a Pb-free solder). A thermal stress is more easily applied to the element joining layer 3 via the die pad 41 from the joining material for attachment in the semiconductor device 1 which has been surface-mounted, as compared with a semiconductor device having a pin terminal mounted by a flow method. However, according to the semiconductor device 1, as described above, it is possible to prevent the element joining layer 3 from becoming fragile in terms of strength by the barrier layer 8. Therefore, it is possible to suppress occurrence of a crack derived from a thermal stress applied to the element joining layer 3, thus making it possible to provide a power semiconductor having a high reliability of heat dissipation.

Further, as shown in FIG. 8, at a base end of the protruding portion 44, there is formed the gap 9 which leads to an interior of the sealing resin 7 from the resin first side surface 73 of the sealing resin 7. That is, the gap 9 is formed between the resin inner surface 75 of the sealing resin 7 and the die pad 41, thereby providing an environment in which oxygen and moisture easily infiltrate into the sealing resin 7. Thus, there is a fear that oxygen infiltrates into a space between the sealing resin 7 and the element joining layer 3, resulting in formation of an environment where the sealing resin 7 (epoxy resin) is partially oxidized and corrosive ions occur. However, the barrier layer 8 is in close contact with the resin inner surface 75 of the sealing resin 7. Thereby, even if oxygen and moisture infiltrate into the gap 9, it is possible to effectively prevent the sealing resin 7 from coming into contact with oxygen and moisture and suppress occurrence of corrosive ions derived from the sealing resin 7.

Further, when a crack occurs in the element joining layer 3 in an inner region of the semiconductor element 2 which is further inside than the lower edge corner 27 of the semiconductor element 2, the crack can be a heat dissipation resistance which transmits heat to the die pad 41 immediately under the semiconductor element 2. For example, as shown in FIG. 11A, the crack 12 which extends long in the horizontal direction so as to divide the conductive channel and the heat dissipation channel between the semiconductor element 2 and the element joining layer 3 immediately under the semiconductor element 2 corresponds to this type of crack. In contrast thereto, according to the semiconductor device 1, the gap 9 which extends from the resin first side surface 73 of the sealing resin 7 does not reach the lower edge corner 27 of the semiconductor element 2. Therefore, even if, for example, corrosive ions coming from the outside of the semiconductor device 1 infiltrate into the gap 9, it is possible to prevent occurrence of a crack in the element joining layer 3 at least in the vicinity of the lower edge corner 27 of the semiconductor element 2. As a result, it is possible to suppress a decrease in heat dissipation via the element joining layer 3.

### [Examination of Suppressed Decrease in Heat Dissipation]

FIG. 15 is a graph which shows a relationship between the number of cycles and the rate of change in heat resistance in the temperature cycle test with regard to Sample 1 and Sample 2. With reference to FIG. 15, an examination is made for an extent of heat dissipation that is suppressed by formation of the barrier layer 8. In FIG. 15, as to Sample 1 and Sample 2 which have been described above, there is shown the rate of changes in heat resistance at the number of cycles of 300, 500, 750, and 1000 in relation to a heat resistance (0%) of the semiconductor device before execution of the temperature cycle test.

First, in the case of Sample 1, a rate of change in heat resistance of the semiconductor device starts to increase around 200 cycles and increases rapidly around 500 cycles. On the other hand, in the case of Sample 2, there is almost no change in heat resistance even after 500 cycles. Further, in Sample 2, the rate of change in heat resistance increases after 500 cycles. However, the rate of change in heat resistance at 1000 cycles is about 10%, and the heat resistance rate can be kept much lower, as compared with the change of about 30% in Sample 1. From the results of this examination, such a finding is obtained that it is possible to suppress occurrence of a crack in the element joining layer 3 by formation of the barrier layer 8 and suppress a decrease in heat dissipation.

The embodiment of the present disclosure has been described as above, and yet the present disclosure can be implemented in other modes.

The embodiment of the present disclosure is an example in every respect and should not be understood in a limited manner and is intended to include changes in every respect.

Features mentioned below can be extracted from this description and the drawings.

### APPENDIX 1-1

A semiconductor device (1) comprising:
a die pad (41);
a semiconductor element (2) which is disposed on the die pad (41);
an element joining layer (3) which is formed between the die pad (41) and the semiconductor element (2) and joins the semiconductor element (2) to the die pad (41);
a sealing resin (7) which covers the die pad (41), the semiconductor element (2), and the element joining layer (3); and
a barrier layer (8) which is formed at a boundary portion (10) between the sealing resin (7) and the element joining layer (3) and blocks corrosive ions derived from the sealing resin (7).

According to this constitution, the barrier layer (8) is formed between the sealing resin (7) and the element joining layer (3), thus, making it possible to prevent the corrosive ions from coming into contact with the element joining layer (3). Thereby, it is possible to suppress corrosion of the element joining layer (3) and prevent the element joining layer (3) from becoming fragile in terms of strength. As a result, even if a stress is applied to the element joining layer (3), it is possible to suppress occurrence of a crack (12) in the element joining layer (3), thus making it possible to suppress a decrease in heat dissipation via the element joining layer (3).

### APPENDIX 1-2

The semiconductor device (1) according to Appendix 1-1, wherein
the sealing resin (7) has an end surface (73, 74) which forms a peripheral outer shape of the sealing resin (7), and
the die pad (41) includes a protruding portion (44) which protrudes outside the sealing resin (7), with the end surface (73, 74) of the sealing resin (7) given as a starting point.

According to this constitution, a portion which leads to an interior of the sealing resin (7) from the end surface (73, 74) of the sealing resin (7) is formed at a base end of the protruding portion (44). Therefore, there is a fear that oxygen and moisture may infiltrate into a space between the sealing resin (7) and the element joining layer (3), resulting in formation of an environment where a constituent material of the sealing resin (7) is oxidized to produce corrosive ions. However, according to this constitution, the barrier layer (8) is formed, thus making it also possible to block this type of corrosive ions.

### APPENDIX 1-3

The semiconductor device (1) according to Appendix 1-2, wherein
the sealing resin (7) has an inner surface (75) which faces the semiconductor element (2), the element joining layer (3), and the die pad (41),
a gap (9) which extends from the end surface (73, 74) of the sealing resin (7) toward the semiconductor element (2) is formed at least between the inner surface (75) of the sealing resin (7) and the die pad (41), and
a part of the barrier layer (8) is held such that the part of the barrier layer (8) is in close contact with the inner surface (75) of the sealing resin (7) in a state of floating from the die pad (41) via the gap (9).

According to this constitution, the gap (9) is formed between the inner surface (75) of the sealing resin (7) and the die pad (41), thereby providing such an environment that oxygen and moisture easily infiltrate into the sealing resin (7). However, the barrier layer (8) is in close contact with the inner surface (75) of the sealing resin (7). Thereby, even if oxygen and moisture infiltrate into the gap (9), it is possible to effectively prevent the sealing resin (7) from coming into contact with oxygen and moisture and suppress occurrence of corrosive ions derived from the sealing resin (7).

### APPENDIX 1-4

The semiconductor device (1) according to Appendix 1-3, wherein
the gap (9) extends from the end surface (73, 74) of the sealing resin (7) along the die pad (41) and the element joining layer (3) and has an end portion (91) on the element joining layer (3), and
the barrier layer (8) includes a separation portion (81) in a state of floating from the die pad (41) and the element joining layer (3) via the gap (9) and a holding portion (82) which is held between the sealing resin (7) and the element joining layer (3) at a portion between a lower edge corner (27) of the semiconductor element (2) and the end portion (91) of the gap (9).

For example, where the crack (12) occurs in the element joining layer (3) in an inner region of the semiconductor element (2) which is further inside than the lower edge corner (27) of the semiconductor element (2), the crack (12) can be a heat dissipation resistance which transfers heat to the die pad (41) immediately under the semiconductor element (2). In contrast thereto, according to this constitution, the gap (9) which extends from the end surface (73, 74) of the sealing resin (7) does not reach the lower edge corner (27) of the semiconductor element (2). Therefore, for example, even if externally-derived corrosive ions infiltrate into the gap (9), it is possible to prevent the crack (12) from occurring in the element joining layer (3) at least in the vicinity of the lower edge corner (27) of the semiconductor element (2). As a result, it is possible to suppress a decrease in heat dissipation via the element joining layer (3).

Moreover, the element joining layer (3) is in close contact with the sealing resin (7) via the barrier layer (8) (holding portion (82)), thus making it possible to reduce a stress which is applied to the element joining layer (3). Close contact with the element joining layer (3) to the sealing resin (7) via the barrier layer (8) also makes it possible to suppress occurrence of the crack (12) in the element joining layer (3).

### APPENDIX 1-5

The semiconductor device (1) according to Appendix 1-4, wherein
the element joining layer (3) integrally includes a main body portion (31) which is held between the die pad (41) and the semiconductor element (2) and a peripheral portion (32) which is formed around the semiconductor element (2), the peripheral portion (32) having an inclined surface (33) which is inclined with respect to the die pad (41), and
the gap (9) is formed such that the gap (9) bends upward along a front surface (42) of the die pad (41) and the inclined surface (33) of the element joining layer (3) in a cross-sectional view.

### APPENDIX 1-6

The semiconductor device (1) according to Appendix 1-5, wherein
the inclined surface (33) of the element joining layer (3) is inclined at an angle (θ1) of not less than 5° and not more than 45° with respect to the front surface (42) of the die pad (41).

### APPENDIX 1-7

The semiconductor device (1) according to any one of Appendix 1-1 to Appendix 1-6, wherein
the semiconductor element (2) includes a power semiconductor which has a first principal surface (21) and an element rear surface (22) at the opposite side thereof and in which a gate electrode (23b) and a source electrode (23a) are formed in the first principal surface (21) and a drain electrode (25) electrically connected to the die pad (41) via the element joining layer (3) is formed in the element rear surface (22).

The temperature cycle test is available as one of various types of reliability tests of the semiconductor device (1). Since a power semiconductor requires a large current to flow through, it is desirable that an electrical resistance value is kept as low as possible. In order to attain a lower resistance value, for example, various types of members (for example, external terminal, inner wire, etc.) which constitute the semiconductor device (1) tend to be large in size, for example, and as a result, a stress which is transferred from these members to the element joining layer (3) will be easily made large. Thus, the crack (12) is more likely to occur in the element joining layer (3) due to the stress. In contrast thereto, according to this constitution, it is possible to suppress corrosion of the element joining layer (3) by the barrier layer (8) and prevent the element joining layer (3) from becoming fragile in terms of strength. Therefore, even if a large stress is applied to the element joining layer (3), it is possible to suppress occurrence of the crack (12) in a broad range.

### APPENDIX 1-8

The semiconductor device (1) according to Appendix 1-7, wherein
the die pad (41) has a loading surface (42) which is loaded with the semiconductor element (2) and a mounting surface (43) which is exposed from the sealing resin (7) as a drain terminal (4) at the opposite side of the loading surface (42),
the semiconductor device (1) further comprising:
a source lead terminal (51) which is electrically connected to the source electrode (23a) inside the sealing resin (7) and exposed from the sealing resin (7), and
a gate lead terminal (52) which is electrically connected to the gate electrode (23b) inside the sealing resin (7) and exposed from the sealing resin (7).

According to this constitution, the semiconductor device (1) can be surface-mounted on a circuit substrate, etc. via the die pad (41) which is the drain terminal (4). The semiconductor device (1) which is of a surface mount type is mounted by reflowing a joining material for attachment to a circuit substrate (for example, a paste for attachment). A stress is more easily applied to the element joining layer (3) via the die pad (41) from the joining material for attachment in the semiconductor device (1) which has been surface-mounted, as compared with a semiconductor device having a pin terminal which is mounted by a flow method. However, according to this constitution, as described above, it is possible to suppress occurrence of the crack (12) derived from a stress applied to the element joining layer (3) by the barrier layer (8), thus making it possible to provide a power semiconductor having a high reliability of heat dissipation.

### APPENDIX 1-9

The semiconductor device (1) according to Appendix 1-7 or Appendix 1-8, wherein
the semiconductor element (2) is formed in a quadrilateral shape, one side of which is not less than 3.0 mm and not more than 8.0 mm.

### APPENDIX 1-10

The semiconductor device (1) according to any one of Appendix 1-7 to Appendix 1-9, wherein
the die pad (41) has a thickness of not less than 1.0 mm and not more than 2.0 mm.

According to this constitution, the die pad (41) has a thickness of not less than 1.0 mm and not more than 2.0 mm and, therefore, a heat resistance of the die pad (41) can be made relatively low. It is, thereby, possible to improve the heat dissipation of the semiconductor device (1).

### APPENDIX 1-11

The semiconductor device (1) according to any one of Appendix 1-1 to Appendix 1-10, wherein
the barrier layer (8) includes an aluminum oxide layer.

### APPENDIX 1-12

The semiconductor device (1) according to any one of Appendix 1-1 to Appendix 1-11, wherein
the element joining layer (3) includes an element joining layer (3) which contains a solder alloy.

For example, where the element joining layer (3) is a solder alloy, a constitution metal of the element joining layer (3) partially reacts with corrosive ions, thereby losing a composition balance of the alloy, and the element joining layer (3) may easily undergo corrosion. However, according to this constitution, it is possible to block the element joining layer (3) from coming into contact with the corrosive ions by the barrier layer (8), thus making it possible to suppress loss of the composition balance of the alloy. As a result, it is possible to prevent the element joining layer (3) from becoming fragile in terms of strength.

### APPENDIX 1-13

The semiconductor device (1) according to any one of Appendix 1-1 to Appendix 1-12, wherein
the sealing resin (7) includes a thermosetting base resin, a silane coupling agent, and a hardening accelerator.

### APPENDIX 1-14

The semiconductor device (1) according to Appendix 1-13, wherein
the thermosetting base resin includes an epoxy resin, and
the hardening accelerator includes a phosphorus-based hardening accelerator.

### APPENDIX 1-15

The semiconductor device (1) according to any one of Appendix 1-1 to Appendix 1-14, wherein
the die pad (41) includes a die pad (41) which contains Cu.

### APPENDIX 1-16

The semiconductor device according to any one of Appendix 1-1 to Appendix 1-15, wherein
the element joining layer (3) has a thickness of not less than 50 μm and not more than 200 μm.

### APPENDIX 1-17

The semiconductor device according to any one of Appendix 1-1 to Appendix 1-16, wherein
the barrier layer (8) has a thickness of not less than 50 nm and not more than 10 μm.

1. A semiconductor device comprising:
a die pad;
a semiconductor element which is disposed on the die pad;
an element joining layer which is formed between the die pad and the semiconductor element and joins the semiconductor element to the die pad;
a sealing resin which covers the die pad, the semiconductor element, and the element joining layer; and
a barrier layer which is formed at a boundary portion between the sealing resin and the element joining layer and blocks corrosive ions derived from the sealing resin.

2. The semiconductor device according to claim 1, wherein
the sealing resin has an end surface which forms a peripheral outer shape of the sealing resin, and
the die pad includes a protruding portion which protrudes outside the sealing resin, with the end surface of the sealing resin given as a starting point.

3. The semiconductor device according to claim 2, wherein the sealing resin has an inner surface which faces the semiconductor element, the element joining layer, and the die pad,
a gap which extends from the end surface of the sealing resin toward the semiconductor element is formed at least between the inner surface of the sealing resin and the die pad, and
a part of the barrier layer is held such that the part of the barrier layer is in close contact with the inner surface of the sealing resin in a state of floating from the die pad via the gap.

4. The semiconductor device according to claim 3, wherein
the gap extends from the end surface of the sealing resin along the die pad and the element joining layer and has an end portion on the element joining layer, and
the barrier layer includes a separation portion in a state of floating from the die pad and the element joining layer via the gap and a holding portion which is held between the sealing resin and the element joining layer at a portion between a lower edge corner of the semiconductor element and the end portion of the gap.

5. The semiconductor device according to claim 4, wherein
the element joining layer includes integrally a main body portion which is held between the die pad and the semiconductor element and a peripheral portion which is formed around the semiconductor element, the peripheral portion having an inclined surface which is inclined with respect to the die pad, and
the gap is formed such that the gap bends upward along a front surface of the die pad and the inclined surface of the element joining layer in a cross-sectional view.

6. The semiconductor device according to claim 5, wherein
the inclined surface of the element joining layer is inclined at an angle of not less than 5° and not more than 45° in relation to the front surface of the die pad.

7. The semiconductor device according to claim 1, wherein
the semiconductor element includes a power semiconductor which has a first principal surface and a second principal surface at the opposite side thereof and in which a gate electrode and a source electrode are formed in the first principal surface and a drain electrode which is electrically connected to the die pad via the element joining layer is formed in the second principal surface.

8. The semiconductor device according to claim 7, wherein
the die pad has a loading surface which is loaded with the semiconductor element and a mounting surface which is exposed from the sealing resin as a drain terminal at the opposite side of the loading surface,
the semiconductor device further comprising:
a source lead terminal which is electrically connected to the source electrode inside the sealing resin and exposed from the sealing resin; and
a gate lead terminal which is electrically connected to the gate electrode inside the sealing resin and exposed from the sealing resin.

9. The semiconductor device according to claim 7, wherein
the semiconductor element is formed in a quadrilateral shape, one side of which is not less than 3.0 mm and not more than 8.0 mm.

10. The semiconductor device according to claim 7, wherein
the die pad has a thickness of not less than 1.0 mm and not more than 2.0 mm.

11. The semiconductor device according to claim 1, wherein
the barrier layer includes an aluminum oxide layer.

12. The semiconductor device according to claim 1, wherein
the element joining layer includes an element joining layer which contains a solder alloy.

13. The semiconductor device according to claim 1, wherein
the sealing resin includes a thermosetting base resin, a silane coupling agent, and a hardening accelerator.

14. The semiconductor device according to claim 13, wherein
the thermosetting base resin includes an epoxy resin, and
the hardening accelerator includes a phosphorus-based hardening accelerator.

15. The semiconductor device according to claim 1, wherein
the die pad includes a die pad which contains Cu.

16. The semiconductor device according to claim 1, wherein
the element joining layer has a thickness of not less than 50 μm and not more than 200 μm.

17. The semiconductor device according to claim 1, wherein
the barrier layer has a thickness of not less than 50 nm and not more than 10 μm.
